(19) United States
(12) Patent Application Publication
(10) Pub. No.: US 2004/0163601 A1
(43) Pub. Date: Aug. 26, 2004

(54) Plasma processing apparatus

(76) Inventors: Masanori Kadotani, Kudamatsu (JP); Motohiko Yoshigai, Hikari (JP); Ryujiro Udo, Ushiku (JP); Masatsugu Arai, Chiyoda (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/372,831

(22) Filed: Feb. 26, 2003

(51) Int. Cl. C23C 16/00

(52) U.S. Cl. 118/728

(57) ABSTRACT

A plasma processing apparatus of processing a specimen placed on a table disposed inside of a processing chamber by using plasmas formed in the processing chamber in which the table is disposed to an upper portion thereof and comprises thereon a first member in contact with the specimen and a second member disposed below the first member and which comprises;

a temperature control device disposed inside of the table for controlling the temperature of the outer circumferential zone and the central zone of the table to first and second temperatures, respectively, and

a pressure control device for controlling pressure between the surface of the table and the specimen in contact with the surface at the outer circumferential zone and the inner circumferential zone of the specimen to first and second pressures respectively.

### FIELD OF THE INVENTION

This invention concerns a plasma processing apparatus used, for example, for semiconductor manufacturing processes and, more in particular, it relates to a plasma processing apparatus having a specimen table (holding stage) for placing semiconductor wafers.

### BACKGROUND OF THE INVENTION

Along with increasing integration degree of semiconductor devices in recent years, circuit patterns have been refined more and more and dimensional accuracy required for fabrication has become severer. In addition, improvement for the throughput and coping with the increasing area of products to be processed have been required and temperature controllability of semiconductor wafers during processing has become extremely important.

For example, in the etching process requiring a high aspect ratio (narrow and deep groove), while anisotropic etching is required and a process for applying etching while protecting side walls with an organic polymer has been employed for satisfying the requirement, formation of the organic polymer as the protection film varies depending on the temperature. In this case, when the temperature in the wafer surface of the semiconductor is distributed not uniformly during etching processing, formation of the side wall protection film varies in the wafer surface to sometimes result in a problem that the etching shape is not uniform.

Further, reaction products are sometimes re-deposited on the etching surface to lower the etching rate, in which the reaction products tend to form such a distribution that they are present more at the center of a semiconductor wafer than near the outer circumferential zone of the semiconductor wafer and, as a result, etching rate is lower at the center compared with the vicinity of the outer circumferential zone of the semiconductor wafer and, accordingly, the etching shape in the surface of the semiconductor wafer varies within the wafer surface.

In order to improve this, it is effective to make the temperature near the center of the wafer higher than that near the outer circumferential zone thereby suppressing re-deposition of the reaction products to the etching surface. Accordingly, it is necessary to control the temperature of the ware or the stage such that the temperature of the semiconductor wafer is made uniform within the surface, or distributed such that it is optionally higher for the central side and lower for the outer circumferential side within the surface of the semiconductor wafer during plasma etching, thereby suppressing the effect caused by the distribution of the reaction product.

For the subject described above, Japanese Patent Laid-Open No. H7(1995)-249586 (prior art 1) discloses a technique of providing gas charging/discharging devices for flowing heat conducting helium gases to the outer circumferential side (first opening) and a central side (second opening) of a semiconductor wafer disposed on an electrostatic adsorption electrode respectively and supplying helium gases under gas pressure control between the electrostatic adsorption electrode and semiconductor wafers placed thereon. Further, Japanese Patent Laid-Open No. H9(1997)-129715 (prior art 2) discloses a technique of supplying helium gases at different flow rates to a leak portion and a seal portion on the outer circumferential zone of the substrate respectively to maintain a uniform temperature over the substrate.

Further, Japanese Patent Laid-Open H10(1998)-41378 (prior art 3) discloses a technique of dividing the upper surface of a substrate support for holding the substrate into two zones of an outer circumferential zone and the inner area thereof, providing sealing between them such that the two zones can be put under different gas pressures, and supplying a gas at a high pressure corresponding to the region of the substrate requiring high heat conduction.

Further, for controlling the temperature of a semiconductor wafer during processing, a technique of controlling the temperature at the surface of an electrostatic adsorption electrode on which the wafer is placed (holding stage) is disclosed, for example, in Japanese Patent Laid-Open No. 2000-216140 (prior art 4).

The prior art 5 has a structure in which a plurality of independent coolants flow channels capable of controlling the flow rate of coolant are provided in a metal electrostatic adsorption electrode block constituting the holding stage and a dielectric film is disposed to the surface of the electrode block.

Further, Japanese Patent Laid-Open No. H9(1997)-17770 (prior art 6) discloses a structure for controlling the temperature distribution in the surface of a semiconductor wafer, of providing two systems of coolant flow channels concentrically in the inside of an electrostatic adsorption electrode for circulating coolants at a relatively lower temperature in the coolant flow channel at the outside and coolants at a relatively higher temperature in the coolant flow channel in the inside.

However, no sufficient consideration has been taken in each of the prior arts described above for processing the specimen as an object of processing in a short period of time thereby improving the throughput of the processing.

In the prior arts 1, 2, and 3, a gas supplied for heat conduction between the specimen and the specimen table (electrode) for supporting the specimen is controlled. Specifically, the amount of heat conduction between the specimen and the specimen table is controlled by controlling the flow rate or the pressure of the gas thereby attaining an aimed temperature distribution on the specimen. Plasmas formed above the specimen constitute a main supply source for the thermally conducted heat. Accordingly, the temperature distribution of the specimen depends on the amount of heat of the supply source and, in a case where the amount of heat is small, it may be a worry that the temperature distribution (temperature difference) required for the processing of the specimen can not be attained. That is, there has been a problem that the attainable range for the distribution of the temperature (temperature difference, etc.) is narrow.

In this regard, the prior arts 4 and 5 attain the temperature distribution by supplying coolants, for example, liquid coolants at different temperatures to different portions inside of the specimen table. Since the system has a heat source in addition to the plasmas, the attainable range for the temperature distribution is larger than that in the prior art 1, 2, and 3. However, the techniques of controlling the temperature by the coolants take more time than that in the prior art 1, 2 and 3 till they cause change of temperature in a case where the change of temperature between processing steps. That is, during a period from the input of a set temperature till the change of the temperature of the coolants flowing in the specimen table to attain an equilibrium state in heat exchange relative to the specimen table, the specimen is processed before it reaching a desired state, or processing has to be interrupted until a required temperature is reached, which lowers the throughput of the processing.

Such a problem is particularly conspicuous in a case of processing a specimen in which a plurality of film layers requiring differing processing conditions are formed in one identical semiconductor wafer. For example, in a case where operation conditions (specimen processing conditions) of a semiconductor processing apparatus for processing one of films and the operation conditions for processing at least one of other films are different and where each of the film layers is etched into an identical shape, after completion of etching to the former film, it is necessary to process the latter film after changing the conditions for the etching processing of the semiconductor processing apparatus. However, as the recess time of interrupting the processing in the semiconductor processing apparatus till the change of the processing conditions between the former and the latter is longer, the number of specimens that can be processed per unit time is decreased.

### SUMMARY OF THE INVENTION

This invention intends to provide a plasma processing apparatus having excellent temperature controllability and capable of improving throughput.

This invention further intends to provide a plasma processing apparatus capable of coping with increasing area of a product to be processed and capable of improving the dimensional accuracy for fabrication and throughput.

The foregoing object can be attained according to this invention in a plasma processing apparatus of processing a specimen placed on a table disposed inside of a processing chamber by using plasmas formed in the processing chamber in which

the table is disposed to an upper portion thereof and comprises thereon a first member in contact with the specimen and a second member disposed below the first member and which comprises;

a temperature control device disposed inside the second member for controlling the temperature of the outer circumferential zone and the temperature of the central zone of the table disposed inside the second member independently, and

a gas supply device for supplying heat conducting gases between the first member and the specimen to the outer circumferential zone and the inner circumferential zone of the specimen independently.

Further, the foregoing object is attained by a plasma processing apparatus of processing a specimen placed on a table disposed inside of a processing chamber by using plasmas formed in the processing chamber which comprises;

a temperature control device disposed inside of the table for controlling the temperature of the outer circumferential zone and the central zone of the table to a first temperature and a second temperature respectively, and

a pressure control device for controlling the pressure of a heat conducting gas supplied between the surface of the table and the specimen in contact with the surface to the outer circumferential zone and the inner circumferential zone of the specimen to a first pressure and a second pressures, respectively.

Further, the foregoing object is attained by a plasma processing apparatus of processing a specimen placed on a table disposed inside of a processing chamber and having plural layers on the surface thereof by using plasmas formed in the processing chamber, in which

the table is disposed to an upper portion thereof and comprises thereon a first member disposed thereabove and in contact with the specimen and a second member disposed below the first member and which comprises;

a temperature control device disposed inside of the second member for controlling the temperature of the outer circumferential zone and the temperature of the central zone of the table independently,

a gas supply device for supplying heat conducting gases between the first member and the specimen to the outer circumferential zone and to the inner circumferential zone of the specimen independently, and

a control device for controlling the operations of the temperature control device and the gas supply device based on the obtained information with respect to the plural layers of films.

Further, the foregoing object is attained by a plasma processing apparatus of processing a specimen placed on a table disposed inside of a processing chamber by using plasmas formed in the processing chamber, in which

the table is disposed to an upper portion thereof and comprises thereon a first member in contact with the specimen and a second member disposed below the first member and which comprises;

the table comprises a temperature control device disposed inside of the table for controlling the temperature of the outer circumferential zone and the central zone of the table to a first temperature and a second temperature respectively,

a pressure control device for controlling the temperature of a heat conducting gas supplied between the surface of the table and the specimen in contact with the surface to the outer circumferential zone and the inner circumferential zone of the specimen to a first pressure and a second pressures respectively, and

a control device for controlling the operations of the temperature control device and the pressure control device based on the obtained information with respect to the plural layers of the films.

Further, the foregoing object can be attained in a preferred embodiment of the invention by the provision of the control device for controlling the operations of the temperature control device and the pressure control device upon processing upper films among the plural films based on the obtained information with respect to the lower films thereof.

The present invention can also provide a plasma processing apparatus capable of attaining higher throughput. Further, it can provide a plasma processing apparatus capable of coping with increasing area of a product to be processed and capable of improving the dimensional accuracy for fabrication and capable of improving the throughput.

### BRIEF DESCRIPTION OF THE DRAWINGS

FIG. 1 is an explanatory view showing a preferred embodiment of a plasma processing apparatus according to this invention.

FIG. 2 is a perspective view showing a schematic constitution of a specimen table in the embodiment shown in FIG. 1.

FIG. 3 is a schematic view showing a constitution of coolant flow channels of the embodiment shown in FIG. 2.

FIG. 4 is a schematic view showing a modified embodiment of coolant flow channels of the embodiment shown in FIG. 2.

FIG. 5 is a characteristic graph showing an example of a pressure distribution of a He gas between an electrostatic adsorption electrode and a semiconductor wafer.

FIG. 6 is a characteristic graph showing an example of a surface temperature of a semiconductor wafer by an electrostatic adsorption electrode.

FIG. 7 is a graph showing an example of a surface temperature of a semiconductor wafer in a preferred embodiment of an electrostatic adsorption electrode according to the invention in comparison with the prior art.

FIG. 8 is a graph showing an example of a surface temperature of a dielectric film in a preferred embodiment of an electrostatic adsorption electrode according to the invention in comparison with the prior art.

FIG. 9 is a cross sectional view showing a second preferred embodiment of an electrostatic adsorption electrode according to the invention.

FIG. 10 is across sectional view showing a third preferred embodiment of an electrostatic adsorption electrode according to the invention.

### DETAILED DESCRIPTION OF THE PREFERRED EMBODIMENTS

A plasma processing apparatus according to this invention is to be described in details with reference to preferred embodiments shown in the drawings.

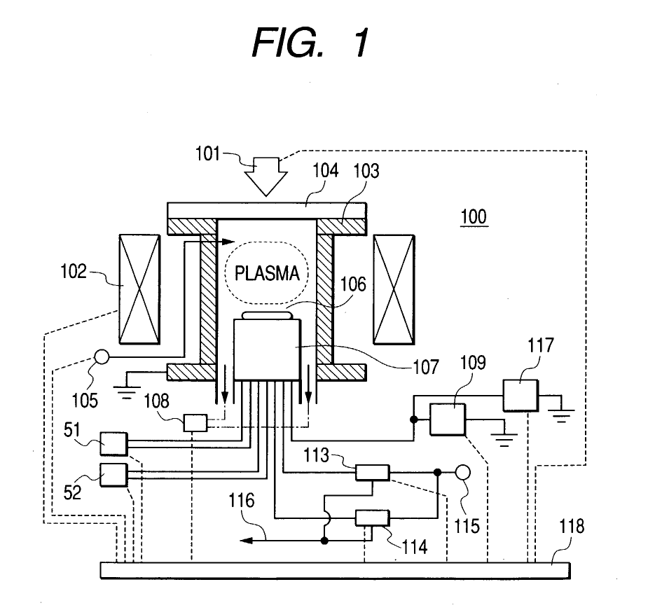

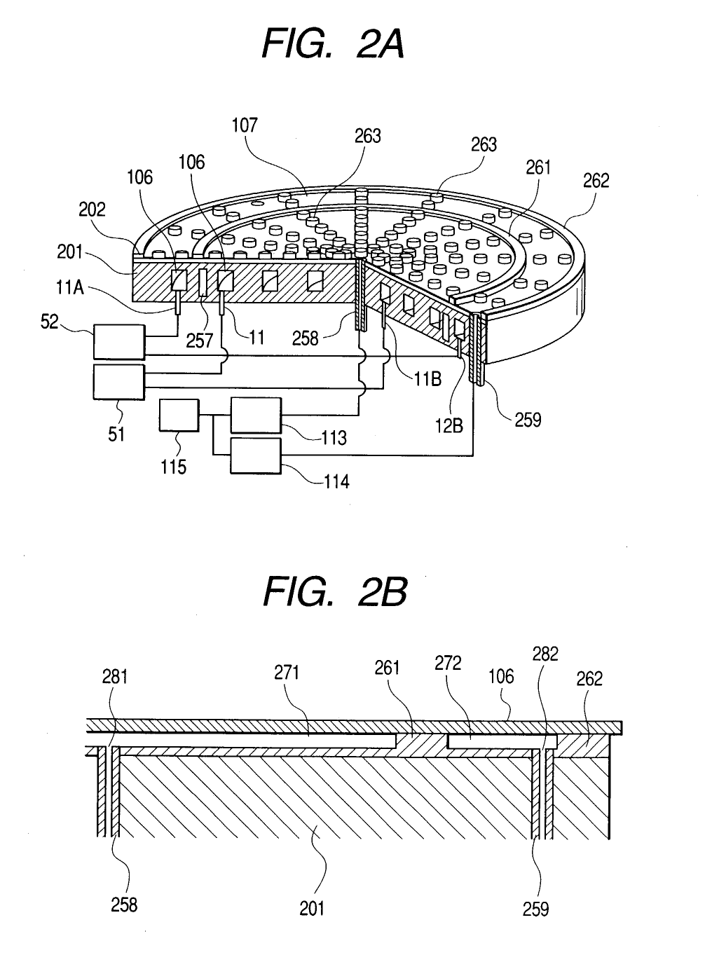

FIG. 1 is a view showing a schematic constitution of a preferred embodiment of a plasma processing apparatus according to this invention. FIG. 2 is a perspective view partially in cross section showing a constitution of an electrode which is used as a stage for supporting a semiconductor wafer 106 of the plasma processing apparatus shown in FIG. 1. The stage is generally adapted to electrostatically attract a semiconductor wafer to hold the same and function as an electrode to plasmas which are formed in the apparatus and considered as a dielectric body (or source of charged particles) in view of the behavior. Then, the stage (specimen table) is hereinafter also referred to as an electrostatic adsorption electrode.

In the plasma processing apparatus 100 shown in FIG. 1, a processing gas stored in a processing gas supply 105 is introduced by way of a predetermined gas channel into the inside of a processing chamber 103 while evacuating a gas in the processing chamber 103 by a vacuum exhausting device 108 not illustrated. In the processing chamber 103, magnetic fields generated by solenoid coils 102, and electromagnetic waves 101, for example, microwaves, UHF and RF introduced from a magnetic wave transmission window 104 are supplied, and the processing gas introduced into the processing chamber 103 are excited into plasmas by the interactions between them.

Further, a specimen table 107 is provided inside the processing chamber 103, and a specimen 106 is placed on the specimen table 107 by a transportation device such as a manipulator arm not illustrated. Further, one or more coolant flow channels for controlling the temperature of the specimen table 107 are formed to the specimen table 107 as will be described later. The flow channels and coolant supply units 51 and 52 are connected such that the coolants flow through the flow channels and then return to the coolant supply units 51 and 52 for circulation. Further, a detection sensor for detecting the temperature of the flowing coolants is disposed to the coolant flow channel, the output from the detection sensor is transmitted, and the circulation amount of the coolants or the temperature of the coolants are controlled in the coolant supply units 51 and 52. In this way, the specimen table 107 is controlled so as to attain predetermined temperature value or temperature distribution.

Further, a gas such as helium previously stored in a gas source 115 is introduced from an introducing pipeline under control to a predetermined pressure by pressure controllers 113 and 114 into a portion between the surface of the specimen table 107 and the rear face of the specimen 106. The introduced gas is supplied for improving the heat conduction between the specimen 106 and the specimen table 107 and, as a result, the temperature of the specimen 106 is controlled.

That is, the specimen 106 is held on the surface of the specimen table 107 by an electrostatic chuck disposed to the specimen table 107 for adsorbing the specimen 106 by electrostatic effect. However, since the surface has fine unevenness, transmission of heat from a heat source such as plasmas through the specimen 106 to the specimen table 107 is sometimes insufficient in a state where they are merely adsorbed. In view of the above, the temperature of the specimen 6 is controlled to a desired value by introducing a gas capable of controlling the heat conductivity between them.

A gas such helium or argon which gives less effect on the behavior of the processing gas in the processing chamber 103 and increases the heat conductivity compared with the case of merely utilizing contact between the specimen 106 and the specimen table 107 is introduced as the heat conducting gas. Further, the helium gas, for example, can change the heat conductivity by controlling the pressure between the specimen 106 and the specimen table 107. That is, it has a feature of increasing the heat conductivity as the gas pressure is higher and decreasing the heat conductivity as it lowers.

Reference numeral 116 denotes a device constituting a heat conducting gas exhaust system. A not illustrated electrode applied with a voltage for conducting electrostatic adsorption is disposed inside of the specimen table 107 and the electrode is connected with an electrostatic adsorption power source 109. Electric power is supplied from the power source to the electrode for electrostatic adsorption as will be described later, by which the specimen 106 is electrostatically adsorbed on the specimen table 107 and by pressure controllers 113 and 114, the specimen 106 is held on the specimen table 107 with a force greater than the pressure of the heat conducting gas controlled for the pressure.

Further, not illustrated another electrode disposed inside the specimen table 107 is connected with a bias power source 117 and a bias voltage is applied form the bias power source 117 to the biasing electrode, thereby drawing ions in the plasmas toward the specimen to process the specimen.

In this embodiment, each of the sensors and the equipment of the apparatus are controlled by a controller 118 connected therewith and giving and receiving signals to and from them. The controller 118 processes the output from each of the sensors, and controls the equipments in accordance with sequence parameters such instructions or set data inputted by an operator, or as predetermined data information stored previously on a connectable memory device. The sequence parameters may be provided in plurality and they may be connected stepwise.

Then, the specimen table 107 as the electrostatic adsorption electrode according to this embodiment has flow channels for fluid acting as coolant or heat medium disposed in the inside thereof and it is used being placed in the plasma processing apparatus according to this invention as will be described with reference to FIGS. 2, 3 and 4.

FIG. 2 is a partially cross sectional view showing a schematic constitution for the upper portion of the specimen table according to the embodiment shown in FIG. 1.

The upper portion of the specimen table 107 comprises, generally, an aluminum electrode block 201, and an electrostatic chuck 202 disposed thereon and also comprises stainless steel guide members, base members and ceramic electrode cover not illustrated. The specimen table 107 is fabricated to have 320 mm diameter and 25 mm entire thickness in a case intended to be used for a semiconductor wafer 106, for example, of 12 inch (300 mm diameter) size. The electrode block 201 and the electrostatic chuck 202 are constituted so as to perform heat conduction, for example, by close contact at a fine gap between them or supply of a heat conducting medium.

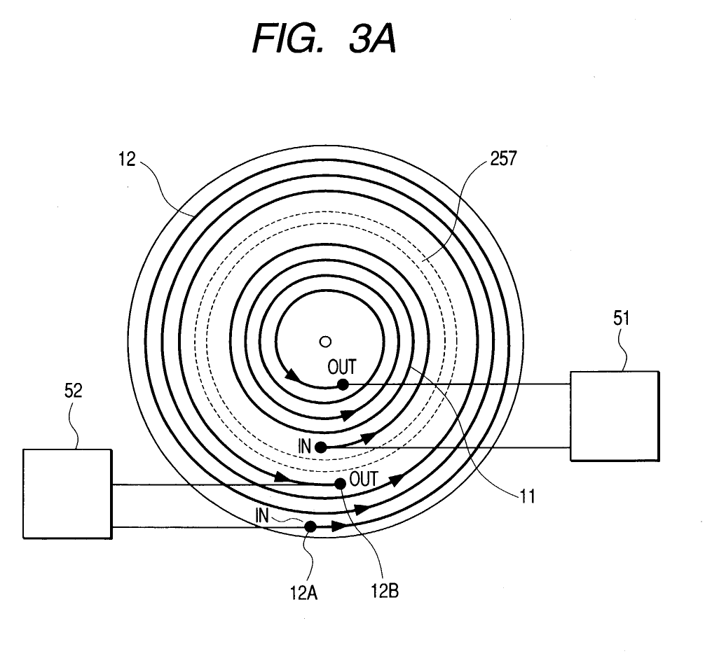

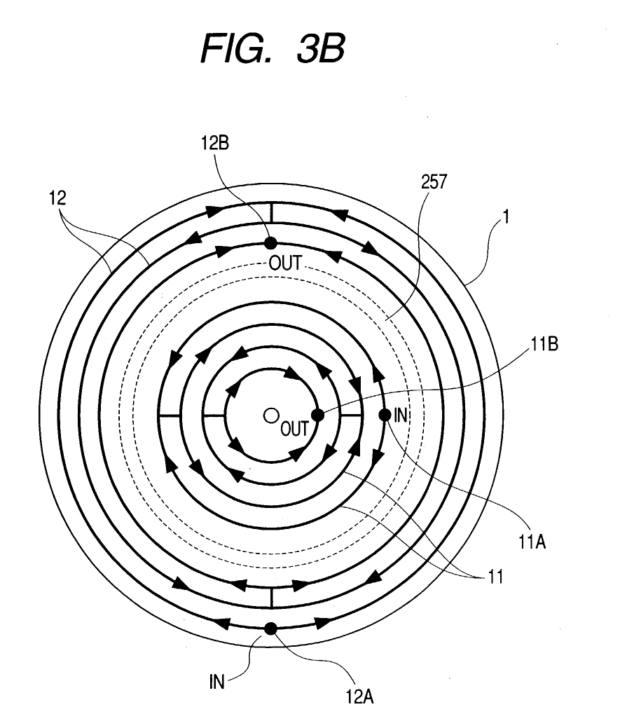

At first, in the electrode block 201, coolant flow channels 11 and 12 are formed spirally being divided into an inner diametrical side and an outer diametrical side at the lower surface thereof as shown in FIG. 3, and substantially concentric slits for restricting heat conduction (radius 90 mm, width 5 mm, height (depth)=18 mm) are formed between them.

Then, the electrostatic chuck 202 has a film comprised of a dielectric material such as alumina ceramics at high purity, and an electrode is disposed to the inside thereof which is supplied with an electric power and applied with a voltage from the electrostatic adsorption power source 109. The film thickness of the dielectric material is 0.1 mm in this embodiment. However, the material and the thickness of the dielectric film are not restricted only to this example and, in a case where it is formed of synthetic resins, a thickness from 0.1 mm to several mm can be selected in accordance with the resin.

Then, as shown in FIG. 2, the electrostatic chuck 202 is provided with pipelines 258 and 259 in communication with the gas source 115 and gas pressure controllers 113 and 114, and the gas from the gas source is introduced while being control to a predetermined pressure by the pressure controllers 113 and 114 to a portion between the surface of the specimen table 107 and the rear face of the specimen 106. Thus, the heat conducting He gas is introduced from gas introduction holes to the gap between the film surface of the dielectric material of the electrostatic chuck 202 and the semiconductor wafer 106.

In FIG. 2A, a plurality of ring-like protrusions 261 and 262 are formed to the upper surface of the electrostatic chuck 202. When the wafer 106 is adsorbed to the upper surface of the electrostatic chuck 202, as shown in FIG. 2B, the upper surfaces of the ring-like protrusions 261 and 262 are in close contact with the rear face of the semiconductor wafer 106 to constitute independent gaps 271 and 272 respectively. Heat conducting gases at predetermined independent pressures are supplied from the gas supply holes 281 and 282 to the gaps 271 and 272. The temperature of the semiconductor wafer 106 is controlled by controlling the pressure of the heat conducting gas, that is, the pressure at the rear face.

Further, in FIG. 2A, protrusions 263 are formed on the upper surface of the electrostatic chuck 202. The height for each protrusion is about 0.1 μm to 10 μm. The protrusions 263 are formed so as to generate adsorption force when the upper portions thereof are in contact with the rear face of the semiconductor wafer 106. Accordingly, the upper faces of the ring-like protrusions 261 and 262 and the protrusions 263 for adsorption are constituted to have substantially the identical height. For the convenient sake of the drawings, the height of the protrusions is depicted as if it was identical with the thickness of the semiconductor wafer 106, the height of the protrusions is outstandingly lower relative to the thickness of the semiconductor wafer 106 in the actual electrostatic chuck 202.

The area for the substantial contact portion between the electrostatic chuck 202 and the wafer 106 is made smaller than the area for the upper surface of the electrostatic chuck 202, in order to decrease the amount of obstacles deposited to the rear face of the wafer and unify the pressure on the rear face upon electrostatic adsorption. Since the wafer adsorption force is generally in proportion with the substantial contact area between the electrostatic chuck and the wafer, it has to be selected properly. Further, the ring-like protrusions 261 and 262 are provided in order to partially control the pressure at the rear face, and the details for which will be described later.

Further, in this embodiment, while the planar shape for the adsorbing protrusions 263 is made circular, it may be of any planar shape so long as the adsorption force can be ensured. For example, the purpose of the invention can be attained also by making the upper surface of the electrostatic chuck 231 as such a surface that can be regarded as a single plane in a macro point of view although having a predetermined surface roughness in a micro point of view, and the surface roughness is decreased only at the portion corresponding to the ring-like protrusions.

Further, coolant flow channels 11 and 12 through which coolants from the coolant supply units 51 and 51 are disposed inside the electrode block 201, and the flow rate and the temperature of the coolants flowing through the flow channels 11 and 12 are controlled independently in the coolant supply units 51 and 52 respectively to form and control the distribution of the temperature inside the electrode block 201. Thus, the distribution of temperature of the electrode block 201 undergoes the effect of the distribution of temperature of the electrostatic chuck 202 disposed thereabove and the temperature distribution of the semiconductor wafer 106 held by the electrostatic chuck 202 can be controlled by the temperature distribution of the electrode block 201.

As shown in FIG. 3, introduction portions 11A and 12A, and discharge portions 11B and 12B of coolants (or heat media) respectively to each of the coolant flow channels 11 and 12 of the electrode block 201, such that the coolant flow channels 11 and 12 can function as heat medium flow channels independent of each other for flowing the temperature controlling coolants.

Then, the introduction portions 11A and 12A and the discharge portions 11B and 12B for each of the coolant flow channels 11 and 12 are connected with the independent coolant supply units 51 and 52 respectively, so that at least one of the flow rate and the temperature of the coolants to be circulated respectively can be controlled individually.

The shape for the arrangement of the coolant flow channels 11 and 12 is not restricted to the spiral shape shown in FIG. 3A. For example, coolant flow channels 11 and 12 are made each into plural concentric shapes in the example shown in FIG. 3B in which the coolants flow being divided into semi-circle direction opposite to each other. In the examples, the coolants are introduced from the flow channels at the outer circumferential zone and flow to the central zone and then discharged out of the semiconductor wafer 106 in each of the coolant flow channels 11 and 12, such that the temperature can be controlled easily so as to be lower for the outer circumferential zone and higher for the central zone of the specimen table 107, that is, the semiconductor wafer 106.

As has been described above, in the plasma processing apparatus according to the preferred embodiment, the semiconductor wafer 106 is placed on the specimen table 107 in the processing chamber 103, and electrostatically adsorbed onto the specimen table 107, while a processing gas such as a chloric or fluoric gas is introduced from the gas source 105, generated microwaves 101 are irradiated to the atmosphere in the processing chamber to excite plasmas, and the distribution and the density of plasmas are controlled by magnetic fields generated by the solenoid coils 102.

Then, a DC voltage and radio frequency wave are applied to the electrode block 201 of the specimen table 107 and the surface of the semiconductor wafer 106 is etched while controlling the temperature of the semiconductor wafer 106 by supplying the helium gas or the coolant to control the temperature control device.

The embodiment of the plasma processing apparatus according to this invention is not restricted only to those shown in the drawings and plasma processing apparatus using other plasma generation device may also be used.

The operation of the specimen table 107 having the electrostatic chuck 202 in this embodiment is to be described. At first, in the specimen table 107, the semiconductor wafer 106 is adsorbed on the dielectric film by a coulomb or Johnson-Lambeck force developed in the dielectric film by applying a high voltage to the electrode of the electrostatic chuck 202 in which two constitutions of single pole type and double pole type are considered for the constitution of the electrode upon applying the high voltage.

The single pole type is a system of providing a uniform potential between the semiconductor wafer 106 and the dielectric film, while the double pole type is a system of providing two or more levels of potential differences between the dielectric films, and any of the systems maybe adopted in this embodiment.

After adsorption, a heat conducting He gas (usually at about 1000 kPa) is introduced from the gas introduction holes 258 and 259 between the semiconductor wafer 106 and the dielectric film of the electrostatic chuck 202. Then, the temperature of the semiconductor wafer 106 is defined in accordance with the conditions such as input heat from the plasmas, heat passage rate through the gap filled with the He gas, heat resistance of the electrode block 201 and, further, the heat passage rate between the coolants circulated in the electrode block 201 and the electrode block 201.

Accordingly, the temperature of the semiconductor wafer 106 may be controlled by providing a mechanism for changing the pressure of the He gas as a heat conducting gas to the electrostatic channel 202, or temperature of the coolants or flow rate of the coolant (that changes the heat passage rate with respect to the electrode block), or by providing a second temperature control mechanism such as a heater.

For example, for flow channel slits 11 and 12 each of a size of 5 mm width×15 mm height, when the flow rate of the coolant at 20° C. is doubled from 2 L/min to 4 L/min, it has been confirmed that the heat passage ratio between the coolant and the electrode block 1 increases from about 200 W/m2K to about 400 W/m2K. Accordingly, since the heat passage rate can be increased by increasing the flow rate of the coolant, even when the heat input from the plasmas increases, the temperature elevation of the electrode block 1 can be suppressed.

By the way, in usual static adsorption electrodes, the temperature distribution is caused due to its structure within the surface of the semiconductor wafer although the input heat from the plasmas is uniform as described below. At first, since the pressure of the He gas introduced between the semiconductor wafer and the dielectric film is higher than the pressure in the chamber (processing chamber) during plasma generation, the He gas leaks from the outermost circumference of the semiconductor wafer W. It is 2 to 5 ml/min in actual measurement.

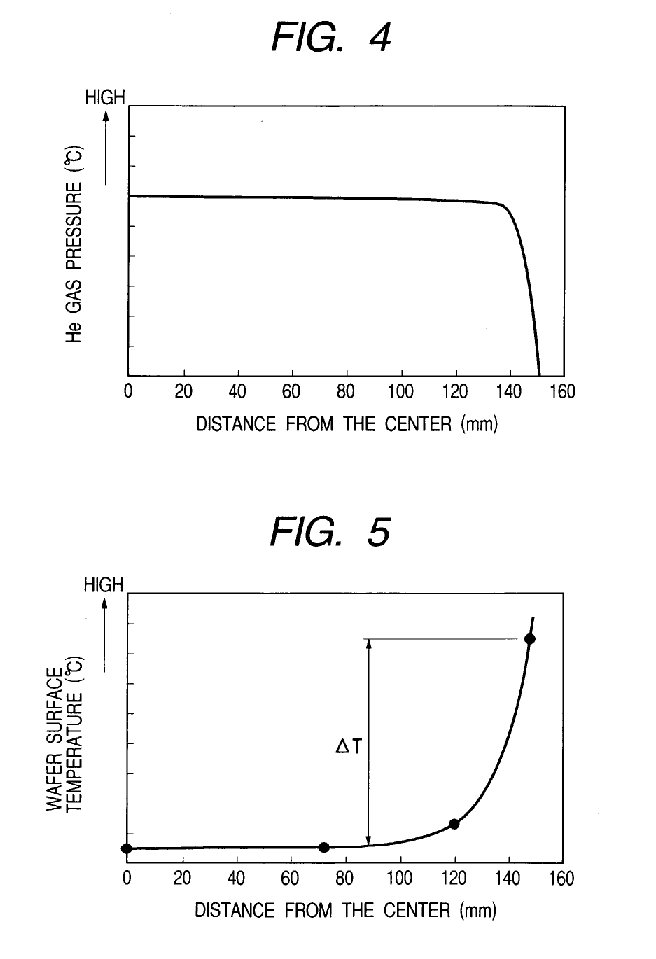

FIG. 4 shows an example for the result of calculation and the graph shows calculation values indicating the pressure distribution at the rear face of a semiconductor wafer determined from the leaked amount of the He gas. As shown in the graph, since the pressure of the He gas at the outermost circumference of the semiconductor wafer is higher than the pressure in the chamber during plasma generation, it is abruptly lowered at the outer circumferential side of the semiconductor wafer.

Then, FIG. 5 shows a surface temperature of semiconductor wafer W in a case where the input heat is uniform within the surface of the semiconductor wafer. The graph shows the result in a case of generating plasmas in an atmosphere introduced with a fluoric gas (1 Pa pressure) and setting the flow rate of the coolant at 5 L/min and the temperature at 35° C. by using the plasma processing apparatus shown in FIG. 1. The abscissa indicates the distance from the center of the semiconductor wafer while the ordinate indicate the temperature at the surface of the semiconductor wafer, each solid circle showing a measured value and a solid line indicating an analysis value.

Accordingly, it can be seen from the graphs that the surface temperature at the outer circumferential side is higher than that at the central side of the semiconductor wafer since the pressure of the He gas lowers.

Then, assuming the temperature difference within the surface of the semiconductor wafer as ΔT, this mainly depend on the RF power applied to the electrostatic adsorption electrode and it reached about 10° C. in a case where an electric power, for example, of 1300 W was applied.

Accordingly, for providing a mild temperature distribution within the surface of the semiconductor wafer, (for example, convex or concave profile) by the electrostatic adsorption electrode, it is necessary to control the temperature distribution while considering the pressure distribution of the He gas.

By the way, while usual electrostatic adsorption electrodes including that of the prior art are shown above, a device for suppressing heat conduction such as a slit 257 having an inner cavity may be disposed between the central side and the outer circumferential side of the electrode block 201 constituting the specimen table 107, and the coolant flow channels 11 and 12 may be disposed to the outer circumferential side and the central side of the slit 257 for suppressing heat conduction.

The slit 257 for suppressing heat conduction is filled at the inside with an atmosphere at a pressure substantial equal with a pressure in the processing chamber or filled with a material of low heat conductivity or kept in a nearly vacuum state, to inhibit conduction of heat between the inner circumferential side and the outer circumferential side of the electrode block 201 and allows a generation of large temperature difference on both sides.

Further, in the constitution described above, the flow channel slit 11 and the slit 12 are independent of each other between the inner circumferential side and the outer circumferential side on both sides of the slit 257 for suppressing heat conduction and at least one of the flow rate or the temperature of the coolant can be controlled individually.

With the constitution described above, since the heat conduction is suppressed in the inside of the electrode block 201, that is, between the outer circumferential side and the central side in the specimen table 107, a larger temperature difference or distribution is formed easily between them and the temperature can be changed to prepare a temperature distribution in a shorter period of time.

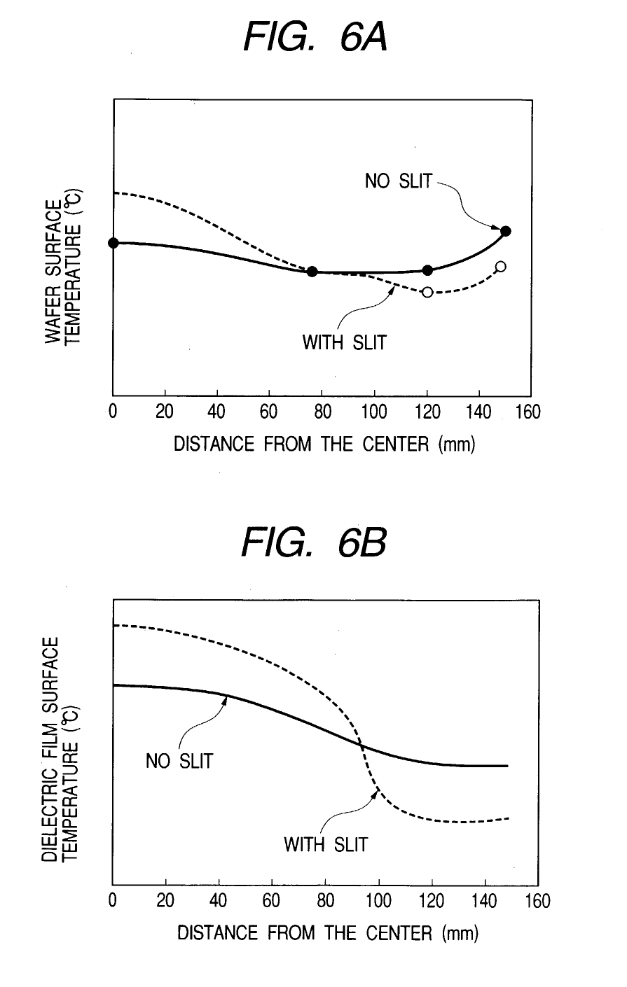

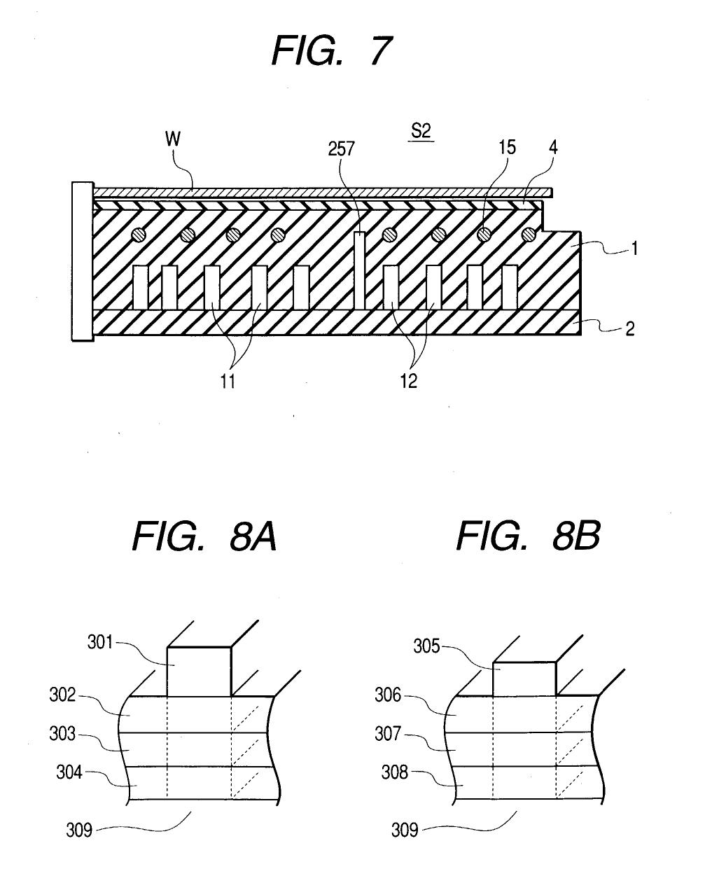

FIG. 7 shows an example for the result of measurement of the temperature distribution of the semiconductor wafer W under the same conditions as those for FIG. 6 by using an electrostatic adsorption electrode S having a slit 257 for suppressing heat conduction to an electrode block 1. It is assumed here such a case that the temperature for the central side is made higher relatively to the temperature at the outer circumferential side. In this case, the RF power to the specimen table 107 (electrode block 201) is set from 100 to 1300 W, the coolant flow rate in the flow channel is set to 1 to 4 L/min, and the coolant flow rate in the flow channel 12 is set within a range from 4 to 8 L/min.

As shown in FIG. 6A, in the specimen table 107 (electrode block 201) provided with the slit 257 for suppressing heat conduction of the embodiment according to the invention, it can be seen that the temperature for the central side at the surface of the semiconductor wafer 106 can be made sufficiently higher while suppressing the temperature lower at the outermost circumferential side on the surface of the semiconductor wafer 6.

Then, FIG. 6B shows a result of analysis for the surface temperature of the electrostatic chuck 202 (dielectric film). As shown in the graph, since the slit 257 for suppressing heat conduction is disposed also in this case, it can be seen that the temperature distribution at the surface of the dielectric film is remarkable and a so-called well-modulated temperature distribution is obtained. It can be also seen that the temperature distribution varies greatly at the slit 257 for suppressing heat conduction as a boundary.

In the specimen table 107 as described above, the pressure of the He gas is generally lowered at the outermost circumferential side of the semiconductor wafer and the temperature increases at the outermost circumferential side of the semiconductor wafer due to the structure thereof. Accordingly, in this embodiment, it is necessary to situate the slit 257 for suppressing heat conduction to an appropriate position in order to suppress the temperature lower at the outermost circumferential side and increase the temperature at the central side of the semiconductor wafer.

In this embodiment, a good result is obtained by situating the slit 257 for suppressing heat conduction such that the distance form the center is within a range of 80 to 120 mm in a case intended to be used for a semiconductor wafer having, for example, 300 mm diameter. In a case where the diameter of the semiconductor wafer is 200 mm, it is within a range from 60 to 80 mm.

Accordingly, it can be seen from the result that the slit 257 for suppressing the heat conduction is preferably disposed within a range from 50 to 80% for the radius of the electrode block 201 in the specimen table 107 of the embodiment according to the invention.

A temperature distribution desired for the semiconductor wafer in the plasma processing is usually a moderate convex or concave distribution in the circumferential direction and, accordingly, the slit 257 for suppressing the heat conduction is preferably formed into a concentric shape.

On the other hand, the cross sectional shape of the slit 257 for suppressing heat conduction is preferably rectangular or trapezoidal in a view point of the fabrication. In this case, the size for the height is important and as the height is larger, that is, as it approaches the size for the thickness of the electrode block 201, the effect of suppressing the heat conduction increases. However, when the height of the slit 257 for suppressing heat conduction increases, since the rigidity of the electrode block 201 lowers, a rib may be disposed in the midway of the slit 257 so as not to lower the rigidity of the electrode block 201.

Further, the position for the protrusion 261 disposed on the electrostatic chuck 202 is also important like the positioning for the slit 257 and the flow channels 11 and 12. This is because the pressure of the heat conducting gas is different between the outer circumferential side and the central side (inner circumferential side) of the protrusion 261 and the heat conduction amount is different. Then, it is necessary to conduct the heat of the electrode block 201 to the semiconductor wafer 106 below (or, vice versa, conduct heat of the semiconductor wafer 106 to the electrode block 201), so that the distribution of the temperature of the specimen table 107 properly affects on the distribution of the temperature of the semiconductor wafer 106. In the embodiment described above, it is disposed so as to situate above a portion between the flow channels 11 and 12 like the location of the slit 257 for suppressing heat conduction.

Accordingly, in the embodiment of this invention, the temperature distribution of the semiconductor wafer 106 can be controlled definitely during plasma etching and, as a result, the temperature can be controlled optionally, for example, such that the temperature is uniform within the surface of the semiconductor wafer 106, or controlled to provide a definite state of temperature distribution such as a convex or concave profile. As a result, it can easily cope with the plasma processing of offsetting the distribution of reaction products thereby suppressing re-deposition of the reaction products to the etching surface and can greatly contribute to the improvement of the yield in the processing for the semiconductor wafer 106.

Then, a modified example of the embodiment according to this invention is to be described. FIG. 7 is a modified example of the embodiment according to this invention in which a heater 15 is buried in an electrode block 201. In this modified embodiment, a heater 15 is cast into the electrode block 201 by using the casting technique. In this case, a heater referred to as a sheath heater in which nichrome wire or tungsten wire covered with an insulating material such as alumina and contained in a stainless steel tube or steel tube is used for the heater 15.

In the drawing, the shape of the electrostatic chuck 202 and the constitution for the supply of the heat conducting gas are not illustrated and they have the constitution and the function as described in FIG. 2 and FIG. 3.

Further, as a similar structure, a heater of a constitution in which the dielectric film of the electrostatic chuck 202 is made as a multi-layered constitution with a tungsten film being sandwiched between them, for example, of a film constitution of an alumina/tungsten/alumina structure may also be used as a heater. Further, a constitution of using a tungsten heater also as an electrode for the electrostatic adsorption electrode may also be adopted.

While the preferred embodiment in which a single slit for suppressing heat conduction is formed in the electrode block 201 is shown but plural slits for suppressing heat conduction may optionally provided, which can easily cope with the attainment of a temperature distribution having finer variation patterns and can control the semiconductor wafer to the optional temperature control.

For controlling the specimen table having the electrode block and the electrostatic chuck to a predetermined temperature distribution, it is necessary to provide a plurality of temperature sensors in the electrode block. In this case, since the temperature at the outermost circumference of the semiconductor waver shows a trend of being relatively higher within the wafer surface of the semiconductor, control can be performed while monitoring temperature distribution such as to a convex or concave profile by providing the temperature sensors by at least three positions individually from the center to the outer circumference of the semiconductor wafer.

Then, processing operation for fabricating to process a layerous film formed on the semiconductor wafer 106 is to be described with reference to FIG. 8 to FIG. 10.

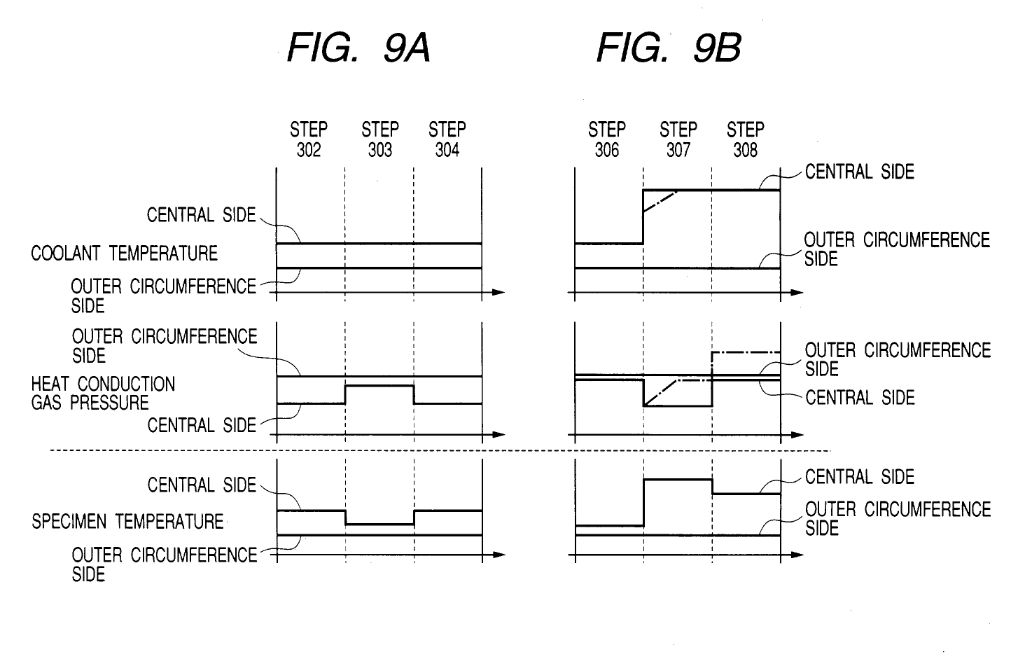

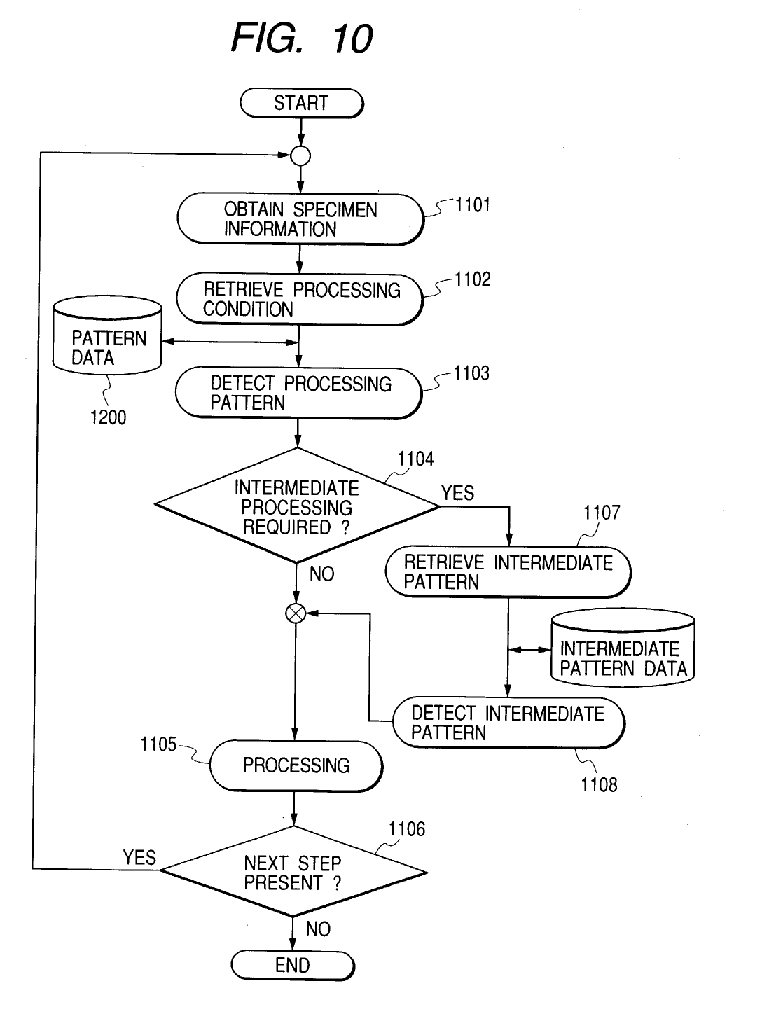

FIG. 8 is a schematic view showing an example of a constitution of a film of the semiconductor wafer surface according to the preferred embodiment of the plasma processing apparatus shown in FIG. 1. FIG. 9 is a graph prepared by patterning the change with time of the operation conditions of the plasma processing apparatus according to this invention upon processing for the embodiment shown in FIG. 8. FIG. 10 is a flow chart showing the outlined flow for the operation of the plasma processing apparatus shown in FIG. 1.

FIG. 8A shows a surface of a semiconductor wafer 106 undergoing the process of successively etching to process films 302, 303 and 304 as an object of processing formed on the underlying portion 309 of the substrate based on the shape of a mask 301. At the surface of the semiconductor wafer 106, films 302 and 303, and 303 and 304 are laminated by stacking each by way of the boundary portion (in contact with the boundary). For conducting approximately uniform processing on the surface of the semiconductor wafer 106 with the film of such a constitution, the optimal temperature distribution differs depending on the plural films as the distribution of the temperature within the direction of the wafer surface.

For example, a state where the temperature for the central side is higher by 5° C. than the outer circumferential side of the wafer is the optimal condition for the film 302. The optimal condition for processing the film more uniformly in the direction within the surface in view of the film property is such that the state of the temperature distribution where the temperature at the central side is higher than the outer circumferential side by 2° C. for the film 303 and by 5° C. for the film 304. Underlying portion 309 is a portion not basically applied with processing.

On the other hand, FIG. 8B shows the surface of the semiconductor wafer 106 which undergoes a process of successively etching to process the films 306, 307 and 308 as the object of processing formed on a substrate 309. On the surface of the semiconductor wafer 106, films 306 and 307, and films 307 and 308 are laminated by stacking by way of the boundary portions respectively (in contact with the boundary). For performing processing more uniformly on the surface of the semiconductor wafer 106 for the films of the constitution described above, the film 306 has a property that the optimal temperature distribution along the direction within the surface of the wafer is such optimal condition where the temperature at the central side is higher by 5° C. than the outer circumferential side. The optimal condition for processing the film more uniformly in the direction within the surface in view of the film property is such that the state of the temperature distribution where the temperature at the central zone is higher than the outer circumferential zone by 15° C. for the film 306, by 18° C. for the film 307 and by 15° C. for the film 304.

The plasma processing apparatus of this embodiment is operated upon processing the films of such a constitution, while controlling the temperature and the flow rate of coolants flowing through the flow channels 11 and 12 formed inside of the specimen table 107, or while controlling the pressures of the heat conducting gases supplied respectively to the outer circumferential side and the central side between the semiconductor wafer 106 and the static chuck 202. FIG. 9A and FIG. 9B are graphs showing the change of the operation conditions corresponding to FIG. 8A and FIG. 8B, respectively.

In this embodiment, the temperature and the flow rate of the coolants and the pressure of the gas are controlled while considering the change of the temperature for attaining the temperature distribution of the semiconductor wafer 106 determined for the processing each of the stacked films. In the example shown in FIG. 9A and FIG. 9B corresponding to FIG. 8A and FIG. 8B, respectively, while the temperature distribution of the semiconductor wafer 106 is controlled by changing the pressure of the heat conducting gas in the former, the pressure of the heat conducting gas and the temperature of the coolants are changed to change the temperature distribution of the specimen table 107 in the latter thereby controlling the temperature distribution of the semiconductor wafer 106.

In FIG. 9A, the temperature difference of the temperature distribution to be changed is a difference from 5° C. to 3° C. and from 3° C. to 5° C. between the film 302 and 303 and the between the films 303 and 304. Accordingly, it is judged that the temperature change can be adjusted by controlling the pressure difference of the heat conducting gas. Then, control by the change of the temperature and the flow rate of the coolants requiring longer time for forming the temperature distribution of the specimen table 107 between the steps 302 and 303 and 304 is suppressed (not changed in this embodiment). On the other hand, in the process from the steps 302 to 303, the difference between the gas pressure on the outer circumferential zone and the gas pressure on the central zone is made greater at step 303, the heat conduction amount is increased in the central zone of the step 303 and to control such that the difference between the temperature for the central zone and the temperature for the outer circumferential zone of the semiconductor wafer 106 is decreased by the control by the heat conducting gas. Further, in the process from the step 303 to 304, the difference between the gas pressure at the outer circumferential zone and the gas pressure at the central zone of the semiconductor wafer 106 is decreased on the contrary in step 304, and it is controlled to increase the temperature difference between the central zone and the outer circumferential zone.

With the constitution described above, since the temperature distribution of the semiconductor wafer 106 can be formed to a desired state corresponding in time to the transient temperature change during processing, there is no requirement of interrupting the processing till the temperature of the specimen table 107 is changed to a predetermined value during processing for each of the films to improve the processing throughput.

FIG. 9B, the temperature difference in the temperature distribution to be changed corresponds to the temperature distribution of 3° C. and 18° C. between the films 306 and 37, and between 18° C. and 15° C. the films 307 and 308. In the process from the step 306 to step 307 in this embodiment, change of the temperature distribution of the semiconductor wafer 106 is as large as from 3° C. to 18° C. of the temperature difference between the temperature of the outer circumferential zone and the temperature of the central zone, which exceeds the range of the temperature difference that can be formed by the pressure difference of the heat conducting gas.

Then, for such large change of the temperature distribution difference, an operation of rapidly amending the change of the difference of the temperature distribution is conducted by the temperature control device and the pressure control device.

For this purpose, before processing the film in the step 307, the processing the for the surface of the semiconductor wafer 106 is interrupted till a predetermined temperature distribution is formed. Specifically, formation of plasmas is interrupted by interrupting the supply of the processing gas. Then, when a predetermined temperature distribution is reached, processing at step 307 is started.

In the process from the step 307 to the step 308, the temperature distribution of the semiconductor wafer 106 changes from 15° C. to 12° C. In this case, it is judged that the temperature distribution can be attained by forming the temperature difference by controlling the pressure difference of the heat conducting gas, and the difference between the gas pressure at the outer circumferential side and the gas pressure at the central side of the semiconductor wafer 106 is increased in the process between the step 307 and step 308 and the temperature difference between the central side and the outer circumferential side of the semiconductor wafer is decreased 106 in the step 308.

As described above, for the large change of the temperature distribution difference, since change of the temperature by the change of the heat condition amount by controlling the gas pressure can be conducted rapidly in a remarkably shorter period of time than that for the change of the temperature or the flow rate of the coolants, it can suppress the interruption of the processing such as interruption for the supply of the processing gas and can improve the throughput of the processing.

In FIG. 9B, the change of the temperature distribution for the specimen table 107 between the step 306 and step 307 is conducted by controlling the temperature and the flow rate of the coolants flowing through the coolant channels 11 and 12 disposed to the electrode block 201 of the specimen table 107 thereby controlling the temperature distribution on the side of the electrode block. Further, the control is also conducted for the pressure of the heat conducting gas by controlling the amount of heat conduction between the electrostatic chuck 202 and the semiconductor wafer 106 by lowering the pressure of the heat conducting gas on the central side of the semiconductor wafer 106. Conditions for the apparatus are controlled so as to increase the temperature on the central side of the semiconductor wafer 106. This is because the temperature difference of the temperature distribution in the semiconductor wafer 106 set at the step 307 is so large as can not be formed only by the pressure difference of the heat conducting gas.

Then, the temperature distribution on the side of the electrode block 201 is not changed (that is, without changing the condition of flowing the coolants through the coolant flow channels 11 and 12) between the step 307, and step 308, but only the pressure of the gas for heat conduction is controlled to change heat conduction, thereby controlling the temperature distribution of the semiconductor wafer 106. Since the temperature difference of the temperature distribution of the semiconductor wafer 106 set in step 308 is 15° C. and this is larger than the maximum value of the temperature difference that can be formed with the pressure difference of the heat conducting gas between the outer circumferential side and the central side of the semiconductor wafer 106, it may be considered that the temperature difference can not be attained only by the pressure difference of the heat conducting gas. However, since the temperature difference is already set to 18° C. in the step 307, the change of the temperature therefrom is about 3° C. and this can be attained only by the control for the pressure of the heat conducting gas.

That is, in this embodiment, the basic distribution of the temperature of the specimen table 107 or the semiconductor wafer 106 placed and held thereon is formed and maintained by controlling the coolants flowing in the coolant flow channels 11 and 12 and change of the distribution difference within a predetermined range from the basic temperature distribution is attained by controlling the pressure of the heat conducting gas.

With the constitution described above, when the apparatus is used for forming the pressure difference of the heat conducting gas in a pressure region such as α region at high pressure or at low pressure where control of the pressure value at high accuracy is difficult, the accuracy of the apparatus is not lowered. Further, it is not required to use such a gas pressure control device which is large in the scale and expensive although the accuracy is high and the semiconductor wafer 106 as the specimen can be processed at higher accuracy.

As described above, in a case of processing the semiconductor wafer having a film structure comprising plural layers, it is desirable, based on the information of the film structure, to previously conduct the operation of amending the change of the difference in the temperature distribution by the temperature control device and the pressure control device when the desired difference of the temperature distribution between the films to be processed successively is larger than a predetermined value, while conduct the operation of amending the change of the temperature distribution by the pressure control device when the difference of the temperature distribution is less than the predetermined value.

Further, in this case, the temperature distribution of the semiconductor wafer 106 may also be formed only by the temperature distribution on the side of the electrode block 201 without making a large pressure difference of the heat conducting gas, and the pressure on the outer circumferential side of the semiconductor wafer 106 may be changed higher in the step 308.

Further, as shown by dotted lines in FIG. 9B, in the process from step 306 to step 307 where the change of the temperature distribution is large, the temperature difference of the specimen table 107 may be formed also by forming the pressure difference of the heat conducting gas in the course of the control for the temperature distribution of the specimen table 107 by the coolants, starting the processing in step 307 while forming the temperature distribution of the semiconductor wafer 106 by using both of them, forming the temperature distribution continuously by the coolants also after starting step 307 to control the pressure difference of the heat conducting gas lower along with increase of the temperature difference, forming the temperature difference of the specimen table 107.

According to this invention, in high-mix low-volume production such as for system LSI, when a large change is caused to a desired temperature difference between plurality layers of film structures of each of wafers, the throughput can be improved remarkably. Further, considering a case of mass-producing single species as in DRAM, where wafers under the same processing conditions (recipe) are processed continuously, the difference of the temperature distribution is also large between first step 308 for the first sheet and step 302 for the second sheet. Also in this case, both the coolants and the heat conducting gas may be used together to amend the temperature difference as an embodiment in which the temperature change is large.

Use of any one of the control by the coolants or control by the heat conducting gas or combination thereof is different depending on the condition required for the processing of films formed on the upper surface of the semiconductor wafer 106 as the target to be processed, and they should be selected based on the information for them. For example, in the processing shown in FIG. 8A and FIG. 9A, the temperature distribution is not changed by the coolants and the pressure control devices 113 and 114, and the gas source 115 are operated so as to control only the pressure of heat conducting gas.

For the instruction of such operations the controller 118 calculates conditions based on the data stored in a predetermined memory device or based on the previously given information and sends them to equipments requiring the operations.

For example, information for the films on the surface of the semiconductor wafer 106, necessary processing and conditions thereof are recorded or stored on the cassette for containing the semiconductor wafer 106 or the wafer per se and are provided by a controller equipped to the apparatus that reads them from the cassette containing the semiconductor wafer or the wafer 106, or receives the information sent therefrom. It is not necessary that the controller is disposed to a portion where the apparatus main body is placed and it may be disposed in a separate place capable of communication by the communication system and constituted such that it can control the operation of a plurality of plasma processing apparatus simultaneously.

Flow of the operations of the plasma processing apparatus is to be described with reference to FIG. 10. FIG. 10 is a flow chart showing the flow for the operation of the plasma processing apparatus according to the embodiment shown in FIG. 1.

In the drawing, the apparatus obtains information regarding the processing conditions for the specimen before processing the semiconductor wafer 106 in step 1101. Such information may also be recorded in the wafer cassette or the wafer per se as described above. Further, the information of the wafer may also be supplied from a communication system instead of directly from the wafer or the cassette. Further, such information may be previously obtained collectively for plural wafers or on every cassette containing plural wafers.

At step 1102, conditions for appropriate processing are retrieved based on the information obtained in step 1101. For example, they are calculated by calculation device equipped in the controller 118, for example, by using previously recorded or stored data in a memory device or a recording device connected with a communication. In this case, each of the conditions may be determined by means of numerical value calculation, or optimal processing conditions may also be selected from the data for processing conditions recorded or stored in the memory 1200 as shown in FIG. 10.

Then, the optimal processing conditions are detected in step 1103 and a processing pattern for processing the film to be processed is determined. The processing pattern also includes the data relevant to constituent example of the films on the surface of the semiconductor wafer, for example, in FIG. 8 and corresponding patterns for controlling temperature and pressure as shown in FIG. 9.

In this case, it is judged in step 1104 whether a pattern for intermediate processing is required or not in addition to the usual processing pattern which is processable continuously. The case requiring the intermediate pattern in addition to the usual processing pattern is, for example, such a case where change of the coolant temperature can not be in time, for example, as between step 304 and step 306 as shown in FIG. 9 in which processing is stopped temporally and then the pressure of inner and outer heat conducting gases is changed in accordance with a predetermined intermediate pattern to control the temperature of the specimen to a determined temperature. Since the processing condition can thus be decided in a short period of time, processing is possible even in a case where the temperature of coolants is being changed along with the charge of the temperature. In the detection of the intermediate pattern in steps 1107 and 1108, the same operation as the detection for the processing pattern in steps in 1102 and 1103 is conducted. The data of the intermediate patterns may be obtained from the storing and recording devices for the processing pattern used in step 1102 or may be obtained from other storing and recording devices. There may be also an intermediate pattern for amending the temperature difference with no interruption of the processing since the change of the coolant temperature is relatively small.

Actual processing is conducted in step 1105 based on the processing conditions thus detected.

After the completion of the processing, it is judged whether other wafer processing is necessary or not. If it is judged necessary, the flow returns to the step 1101 and conducts other wafer processing.

As has been described above, according to the embodiment, the specimen table comprises a temperature control device capable of controlling the temperature independently between the central side and the outer circumferential side of the wafer by the coolants on the side of the electrode block below, and a device for controlling heat conduction by the gas between the central side and the outer circumferential side of the wafer on the side of the electrostatic chuck, which can easily cope with a pattern of a larger range of the temperature distribution than that of the semiconductor wafer to be determined easily and a short period of time.

Then, highly varied processing for the semiconductor wafer by various different temperature distribution patterns can be obtained, which can greatly contribute to the improvement of the performance of the semiconductor wafer.

Further, according to the plasma processing apparatus of the embodiment described above, since the temperature control for the semiconductor wafer can be set optionally and this can easily cope also with uniform etching, the yield of the semiconductor devices can be improved remarkably and the production cost can be reduced effectively.

Further, the time for interrupting the processing can be shortened to greatly improve the throughput for the processing of semiconductors.

As has been described above, the present invention can provide a plasma processing apparatus capable of attaining higher throughput. Further, the invention can provide a plasma processing apparatus capable of coping with increase in the area of products to be processed, improving the dimensional accuracy for fabrication, and improving the throughput.

What is claimed is:

1. A plasma processing apparatus of processing a specimen placed on a table disposed inside of a processing chamber by using plasmas formed in the processing chamber in which
the table is disposed to an upper portion thereof and comprises thereon a first member in contact with the specimen and a second member disposed below the first member,
the apparatus comprising:
temperature control means disposed inside the second member for controlling the temperature of the outer circumferential zone and the temperature of the central zone of the table disposed inside the second member independently; and
gas supply means for supplying heat conducting gases between the first member and the specimen to the outer circumferential zone and the inner circumferential zone of the specimen independently.

2. A plasma processing apparatus of processing a specimen placed on a table disposed inside of a processing chamber by using plasmas formed in the processing chamber,
the apparatus comprising:
temperature control means disposed inside of the table for controlling the temperature of the outer circumferential zone and the central zone of the table to a first temperature and a second temperature respectively; and
pressure control means for controlling the pressure of a heat conducting gas supplied between the surface of the table and the specimen in contact with the surface to the outer circumferential zone and the inner circumferential zone of the specimen to a first pressure and a second pressure, respectively.

3. A plasma processing apparatus as defined in claim 1 or 2, wherein
the temperature control means conducts temperature control by coolant and the apparatus has
means for providing desired data of temperature distribution of the table corresponding to the process for the processing of the specimen, in which
the temperature control means and the pressure control means conduct operation for amending the change of the is temperature distribution when the change of the temperature distribution along with the progress of the processing process is larger than a predetermined value, and the pressure control means conducts operation for amending the change of the temperature distribution when the difference of the temperature distribution is smaller than the predetermined value.

4. A plasma processing apparatus of processing a specimen placed on a table disposed inside of a processing chamber and having plural layers on the surface thereof by using plasmas formed in the processing chamber, in which
the table is disposed to an upper portion thereof and comprises thereon a first member in contact with the specimen and a second member disposed below the first member, the apparatus comprising:
temperature control means disposed inside of the second member for controlling the temperature of the outer circumferential zone and the temperature of the central zone of the table independently;
gas supply means for supplying heat conducting gases between the first member and the specimen to the outer circumferential zone and to the inner circumferential zone of the specimen independently; and
control means for controlling the operations of the temperature control means and the gas supply means based on the obtained information with respect to the plural layers of films.

5. A plasma processing apparatus of processing a specimen placed on a table disposed inside of a processing chamber by using plasmas formed in the processing chamber in which
the table is disposed to an upper portion thereof and comprises thereon a first member in contact with the specimen and a second member disposed below the first member,
the apparatus comprising:
temperature control means disposed inside of the table for controlling the temperature of the outer circumferential zone and the central zone of the table to a first temperature and a second temperature respectively;
pressure control means for controlling the temperature of a heat conducting gas supplied between the surface of the table and the specimen in contact with the surface to the outer circumferential zone and the inner circumferential zone of the specimen to a first pressure and a second pressure, respectively; and
control means for controlling the operations of the temperature control means and the pressure control means based on the obtained information with respect to the plural layers of the films.

6. A plasma processing apparatus as defined in claim 4 or 5, comprising;
control means for controlling the operations of the temperature control means and the pressure control means upon processing upper films, among the plural films, based on the obtained information with respect to the lower films thereof.

7. A plasma processing apparatus as defined in claim 4 or 5, wherein
the temperature control means conducts temperature control by coolants,
the apparatus comprising;
means for providing a desired data for the temperature distribution of the table corresponding to the process for the processing of the specimen, in which
the temperature control means and the pressure control means conduct operation for amending the change of the temperature distribution when the desired difference of the temperature distribution between the films processed continuously is larger than a predetermined value and the pressure control means conducts operation of amending the change of the temperature distribution when the difference of the temperature distribution is smaller than the predetermined value based on the obtained information on the films of the plural layers.
